(19) United States
(12) Patent Application Publication
(10) Pub. No.: US 2010/0237898 A1
(43) Pub. Date: Sep. 23, 2010

(54) OVERCURRENT DETECTING CIRCUIT AND POWER SUPPLY DEVICE

(76) Inventors: Hiroyuki KIKUTA, Kyoto (JP); Norihiro KAWAGISHI, Shizuoka (JP); Yuichi OHKUBO, Gunma (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/724,782

(22) Filed: Mar. 16, 2010

(30) Foreign Application Priority Data
Mar. 19, 2009 (JP) 2009-068279

(51) Int. Cl. G01R 31/36

(52) U.S. Cl. 324/771

(57) ABSTRACT

An overcurrent detecting circuit includes a comparison transistor, a constant current source circuit, a subtraction circuit, and a comparison circuit. The comparison transistor is used for comparison with a main transistor provided in the power circuit. The constant current source circuit supplies a constant current to the comparison transistor. The subtraction circuit subtracts a voltage corresponding to a power supply voltage from a voltage between a drain and a source of the comparison transistor and outputs a voltage indicating the subtraction result. The comparison circuit compares the voltage output from the subtraction circuit with a voltage corresponding to a source voltage of the main transistor and outputs a voltage indicating the comparison result.

### CROSS-REFERENCE TO RELATED APPLICATIONS

This application is based on and claims priority under 35 U.S.C. §119 from Japanese Patent Application No. 2009-068279 filed on Mar. 19, 2009, the disclosure of which is incorporated by reference herein.

### RELATED ART

1. Field of the Disclosure

The disclosure relates to an overcurrent detecting circuit and a power supply device and, more particularly, to an overcurrent detecting circuit that detects an overcurrent flowing through a main transistor of a power circuit and a power supply device including the overcurrent detecting circuit.

2. Description of the Related Art

Japanese Patent Application Laid-Open (JP-A) No. 2007-244128 discloses an overcurrent detecting circuit that detects an overcurrent flowing through a main transistor of a switching regulator. The overcurrent detecting circuit includes a selector that outputs a drain voltage or a source voltage of the main transistor according to the on or off state of the main transistor, a reference voltage circuit that outputs a voltage, which is the product of the on-state resistance of a comparison transistor having a gate to which a gate voltage when the main transistor is turned on is applied and a current from a constant current source, and a comparison circuit that compares the output of the selector with the output of the reference voltage circuit.

In the comparison circuit of the overcurrent detecting circuit, variable resistors individually generate a current corresponding to the output of the selector and a current corresponding to the output of the reference voltage circuit, and a current mirror circuit compares the generated currents.

In the technique disclosed in JP-A No. 2007-244128, an overcurrent flowing through the main transistor is detected by the comparison between the drain voltage of the main transistor and the drain voltage of the comparison transistor based on a ground level. Therefore, when the main transistor is operated by the bootstrap, the overcurrent necessarily is accurately detected.

### INTRODUCTION TO THE INVENTION

The present disclosure has been made in view of the above circumstances and provides an overcurrent detecting circuit and a power supply device.

According to an aspect of the disclosure, there is provided an overcurrent detecting circuit including: a comparison transistor which is used for comparison with a main transistor provided in a power circuit; a constant current source circuit which supplies a predetermined constant current to the comparison transistor; a subtraction circuit which subtracts a voltage corresponding to a power supply voltage generated by the power circuit from a voltage difference between a drain and a source of the comparison transistor and outputs a voltage indicating a subtraction result; and a comparison circuit which compares the voltage output from the subtraction circuit with a voltage corresponding to a source voltage of the main transistor and outputs a voltage indicating a comparison result.

### BRIEF DESCRIPTION OF THE DRAWINGS

Exemplary embodiments of the present disclosure will be described in detail based on the following figures, wherein:

FIG. 1 is a circuit diagram (partial block diagram) illustrating the structure of a power supply device according to a first exemplary embodiment;

FIG. 2 is a diagram illustrating the operation of the power supply device according to the first exemplary embodiment and is also a circuit diagram illustrating the structure of a general subtractor;

FIG. 3 is a diagram illustrating the operation of the power supply device according to the first exemplary embodiment and is also circuit diagram illustrating a variation in the position of a voltage V+;

FIG. 4 is a flowchart illustrating the flow of the process of an overcurrent detection control program according to the first exemplary embodiment; and

FIG. 5 is a circuit diagram (partial block diagram) illustrating the structure of a power supply device according to a second exemplary embodiment.

### DETAILED DESCRIPTION

The exemplary embodiments of the present disclosure are described and illustrated below to encompass an overcurrent detecting circuit and a power supply device and, more particularly, to an overcurrent detecting circuit that detects an overcurrent flowing through a main transistor of a power circuit and a power supply device including the overcurrent detecting circuit. Of course, it will be apparent to those of ordinary skill in the art that the preferred embodiments discussed below are exemplary in nature and may be reconfigured without departing from the scope and spirit of the present disclosure. However, for clarity and precision, the exemplary embodiments as discussed below may include optional steps, methods, and features that one of ordinary skill should recognize as not being a requisite to fall within the scope of the present disclosure. Hereinafter, an exemplary embodiment of the present disclosure will be described in detail with reference to the drawings.

### First Exemplary Embodiment

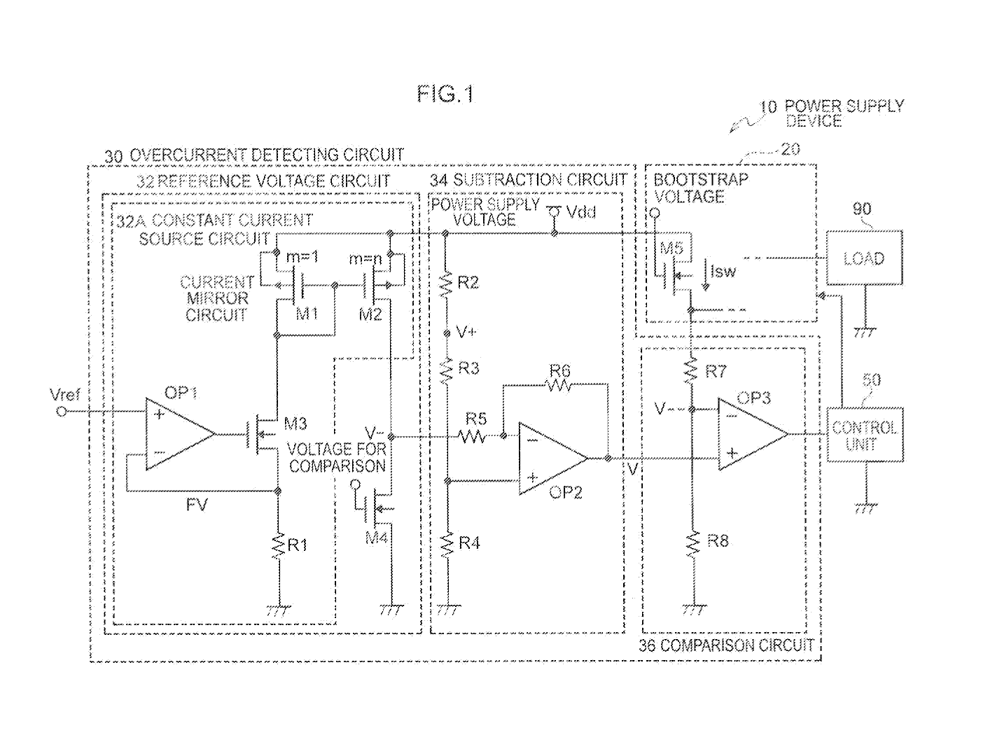

FIG. 1 is a diagram illustrating the structure of a power supply device 10 according to an exemplary embodiment.

As shown in FIG. 1, the power supply device 10 according to this exemplary embodiment includes a power circuit 20, an overcurrent detecting circuit 30, and a control unit 50. The power circuit 20 includes a switching regulator. The overcurrent detecting circuit 30 is provided in the power circuit 20 and detects an overcurrent flowing through a main transistor M5 which is an NMOS transistor. The control unit 50 controls the overall operation of the power supply device 10.

The power circuit 20 generates power supplied to a load 90 by the operation of the main transistor M5. The power circuit 20 according to this exemplary embodiment is configured with a switching regulator in which the main transistor M5 is operated by a bootstrap. A step-up switching regulator or a step-down switching regulator may be applied.

A power supply voltage V_{dd} generated by the power circuit 20 is applied to a drain of the main transistor M5. A source of the main transistor M5 is connected to an element other than the power circuit 20. Since a known power circuit is used as the power circuit 20 according to this exemplary embodiment, the detailed circuit structure of the power circuit 20 is not shown.

The overcurrent detecting circuit 30 according to this exemplary embodiment includes a reference voltage circuit 32, a subtraction circuit 34, and a comparison circuit 36. The reference voltage circuit 32 according to this exemplary embodiment includes a constant current source circuit 32A and a comparison transistor M4 which is an NMOS transistor.

The constant current source circuit 32A according to this exemplary embodiment includes a buffer amplifier OP1, which is a unity-gain operational amplifier (hereinafter, referred to as an “op amp”), an NMOS transistor M3, a resistor R1, a PMOS transistor M1, and a PMOS transistor M2.

A predetermined reference voltage V_{ref} is applied to a non-inverting input terminal of the buffer amplifier OP1. An output terminal of the buffer amplifier OP1 is connected to a gate of the NMOS transistor M3. A source of the NMOS transistor M3 is connected to an inverting input terminal of the buffer amplifier OP1. Therefore, since a reference voltage V_{ref} is applied to the non-inverting input terminal and a feedback voltage FV is applied to the inverting input terminal in the buffer amplifier OP1, the gate voltage of the NMOS transistor M3 is adjusted such that the feedback voltage FV is equal to the reference voltage V_{ref}. In the power supply device 10 according to this exemplary embodiment, a band gap reference voltage source is used as a voltage source of the reference voltage V_{ref}, but the disclosure is not limited thereto. For example, other reference voltage sources, such as a reference voltage source formed by combining a depression-type MOS transistor and an NMOS transistor, may be applied.

The PMOS transistor M1 and the PMOS transistor M2 have gates which are connected to each other and drains to which the power supply voltage V_{dd} is applied. The PMOS transistor M1 has a source connected to a gate thereof and the source of PMOS transistor M1 is connected to the ground through the NMOS transistor M3 and the resistor R1. The source of the PMOS transistor M2 is connected to the ground through the comparison transistor M4. In the constant current source circuit 32A according to this exemplary embodiment, the PMOS transistor M1 and the PMOS transistor M2 form a current mirror circuit. In addition, in the constant current source circuit 32A according to this exemplary embodiment, the area ratio of the PMOS transistor M1 to the PMOS transistor M2 is 1:n.

The gate of the comparison transistor M4 is turned on all the time by the comparison transistor M4 and a comparison voltage whose on-state resistance does not vary is applied to the gate of the comparison transistor M4. The comparison transistor M4 and the main transistor M5 according to this exemplary embodiment are manufactured by the same process.

The subtraction circuit 34 includes five resistors R2, R3, R4, R5 and R6 and a subtractor OP2 which is an op amp for subtraction.

The resistors R2, R3 and R4 are connected in series in this order. The power supply voltage V_{dd} is applied to a terminal of the resistor R2, and a terminal of the resistor R4 is connected to the ground. An inverting input terminal of the subtractor OP2 is connected to a connection line between the PMOS transistor M2 and the comparison transistor M4 of the reference voltage circuit 32 through the resistor R5. A non-inverting input terminal of the subtractor OP2 is connected to a connection line between the resistor R3 and the resistor R4. An output terminal of the subtractor OP2 is connected to the inverting input terminal of the subtractor OP2 itself through the resistor R6.

The comparison circuit 36 includes two resistors R7 and R8 and a comparator OP3 which is an op amp for comparison.

The resistors R7 and R8 are connected in series in this order. The source of the main transistor M5 in the power circuit 20 is connected to a terminal of the resistor R7 and a terminal of the resistor R8 is connected to the ground. An inverting input terminal of the comparator OP3 is connected to a connection line between the resistor R7 and the resistor R8. A non-inverting input terminal of the comparator OP3 is connected to the output terminal of the subtractor OP2. An output terminal of the comparator OP3 is connected to the control unit 50.

The gate of the main transistor M5 is turned on all the time by the main transistor M5 and a bootstrap voltage whose on-state resistance does not vary is applied to the gate of the main transistor M5. The power circuit 20 is connected to the control unit 50. The operation of the power circuit 20 is controlled by the control unit 50.

As the operation of the power supply device 10 according to this exemplary embodiment, the operation of the overcurrent detecting circuit 30 particularly related to the disclosure will be described.

The reference voltage V_{ref} without temperature dependence is buffered by the buffer amplifier OP1. A current generated by the reference voltage V_{ref} and the resistor R1 flows through the current mirror circuit which includes the PMOS transistor M1 and the PMOS transistor M2 with an area that is n times more than that of the PMOS transistor M1 and thus the current value is increased by n times. A voltage corresponding to a voltage V− that is generated by the product of the current value and the on-state resistance of the comparison transistor M4 is applied to the inverting input terminal of the subtractor OP2. A voltage corresponding to a voltage V+generated by dividing the power supply voltage V_{dd} by the resistors R2 to R4 is applied to the non-inverting input terminal of the subtractor OP2.

When the on-state resistance of the comparison transistor M4 is Rₒₙ′ and the resistance values of the resistors R1, R2, R3 and R4 are R₁, R₂, R₃ and R₄, the voltage V− and the voltage V+ are represented by the following Equations 1 and 2. In Equation 1, a term related to the current which flows through the resistor R5 and the resistor R6 is omitted. However, since the current is as small as negligible, the term is not included in Equation 1. In Equation 2, in order to avoid confusion caused by a complicated arithmetic equation, the voltage V+ is positioned between the resistor R2 and the resistor R3.

$$\begin{matrix}V -= n \times \frac{{V}_{rct}}{{R}_{1}} \times {R}_{on}^{′} & Equation ( 1 ) \\ V += \frac{{R}_{3} + {R}_{4}}{{R}_{2} + {R}_{3} + {R}_{4}} \times {V}_{dd} & Equation ( 2 )\end{matrix}$$

Therefore, when the resistance values of the resistors R5 and R6 are R₅ and R₆, a voltage V output from the subtractor OP2 is represented by the following Equation 3 by the Kirchhoff's law.

$$V = \{ \frac{( {R}_{5} + {R}_{6} ) \times {R}_{4}}{( {R}_{5} + {R}_{6} ) \times {R}_{5}} \} \times \{ \frac{{R}_{3} + {R}_{4}}{{R}_{2} + {R}_{3} + {R}_{4}} \} \times {V}_{dd} - ( \frac{{R}_{6}}{{R}_{5}} ) \times n \times \frac{{V}_{ref}}{{R}_{1}} \times {R}_{on}^{′} \qquad Equation ( 3 )$$

When the resistance values are set under the conditions represented by the following Equation 4 in order to easily set the current value I_{sw} of the current flowing through the main transistor M5, the voltage V is represented by the following Equation 5.

$$\begin{matrix}\frac{( {R}_{5} + {R}_{6} ) \times {R}_{4}}{( {R}_{5} + {R}_{6} ) \times {R}_{5}} = 1 & Equation ( 4 ) \\ V = \{ \frac{{R}_{3} + {R}_{4}}{{R}_{2} + {R}_{3} + {R}_{4}} \} \times {V}_{dd} - ( \frac{{R}_{6}}{{R}_{5}} ) \times n \times \frac{{V}_{ref}}{{R}_{1}} \times {R}_{on}^{′} & Equation ( 5 )\end{matrix}$$

The voltage V is applied to the non-inverting input terminal of the comparator OP3.

When the on-state resistance of the main transistor M5 is Rₒₙ and the resistance values of the resistors R7 and R8 are R₇ and R₈, a voltage V− represented by the following Equation 6 is applied to the inverting input terminal of the comparator OP3.

$$V -- = \frac{{R}_{x}}{{R}_{7} + {R}_{8}} \times {V}_{dd} - \frac{{R}_{8}}{{R}_{7} + {R}_{8}} \times {I}_{sw} \times {R}_{on} \qquad Equation ( 6 )$$

When the voltage V is compared with the voltage V−, the current value I_{sw} is derived as follows.

$$\{ \frac{{R}_{3} + {R}_{4}}{{R}_{2} + {R}_{3} + {R}_{4}} \} \times {V}_{dd} - ( \frac{{R}_{6}}{{R}_{5}} ) \times n \times \frac{{V}_{ref}}{{R}_{1}} \times {R}_{on}^{′} = \frac{{R}_{8}}{{R}_{7} + {R}_{8}} \times {V}_{dd} - \frac{{R}_{8}}{{R}_{7} + {R}_{8}} \times {I}_{sw} \times {R}_{on}$$

$${I}_{sw} = \frac{\frac{{R}_{3} + {R}_{4}}{{R}_{2} + {R}_{3} + {R}_{4}}}{\frac{{R}_{8}}{{R}_{7} + {R}_{8}}} - 1 \times {V}_{dd} - ( \frac{\frac{{R}_{6}}{{R}_{5}}}{\frac{{R}_{8}}{{R}_{7} + {R}_{8}}} ) \times n \times \frac{{V}_{ref}}{{R}_{1}} \times \frac{{R}_{on}^{′}}{{R}_{on}}$$

When the resistance values are set under the conditions represented by the following Equation 7 in order to easily set the current value I_{sw}, the current value I_{sw} is represented by the following Equation 8.

$$\begin{matrix}{R}_{2} : {R}_{3} + {R}_{4} = {R}_{7} : {R}_{8} & Equation ( 7 ) \\ {I}_{sw} = \frac{{R}_{7} + {R}_{8}}{{R}_{8}} \times \frac{{R}_{6}}{{R}_{5}} \times \frac{{R}_{on}^{′}}{{R}_{on}} \times n \times \frac{{V}_{ref}}{{R}_{1}} & Equation ( 8 )\end{matrix}$$

In Equation 8, since (R₇+R₈)/R₈ and (R₆/R₅) are resistance ratios, it is possible to accurately set the resistance values, and the resistance ratios do not have temperature dependence or power supply voltage dependence. In Equation 8, since (Rₒₙ′/Rₒₙ) is the ratio of the on-state resistance of the MOS transistor, the ratio does not have temperature dependence or power supply voltage dependence. In Equation 8, n indicates the area ratio of the transistors in the current mirror circuit, and the area ratio does not have temperature dependence or power supply voltage dependence. The reference voltage V_{ref} does not also have temperature dependence.

Therefore, in Equation 8, only the resistance value R₁ of the resistor R1 is a factor which causes a variation in the absolute value of the current value I_{sw}. The overcurrent detecting circuit 30 can accurately detect an overcurrent even when the main transistor is operated by the bootstrap.

In the above-mentioned equations, the voltage V+ is disposed between the resistor R2 and the resistor R3. In the related art, there is a concept that the voltage V+ is to be the potential between the resistor R3 and the resistor R4. However, in this embodiment, the voltage V+ is the potential between the resistor R2 and the resistor R3 for the following reasons.

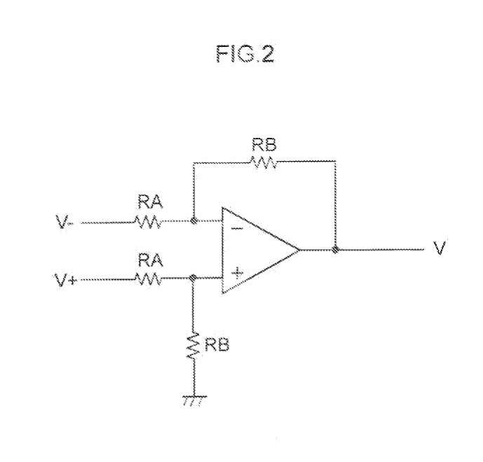

For example, a general subtraction circuit has the structure shown in FIG. 2. The output voltage V from the subtractor in this structure is represented by the following Equation 9. In Equation 9, R_{A} indicates the resistance value of a resistor RA, and R_{B} indicates the resistance value of a resistor R_{B}.

$$V = ( ( V + ) - ( V - ) ) \times \frac{{R}_{B}}{{R}_{A}} \qquad Equation ( 9 )$$

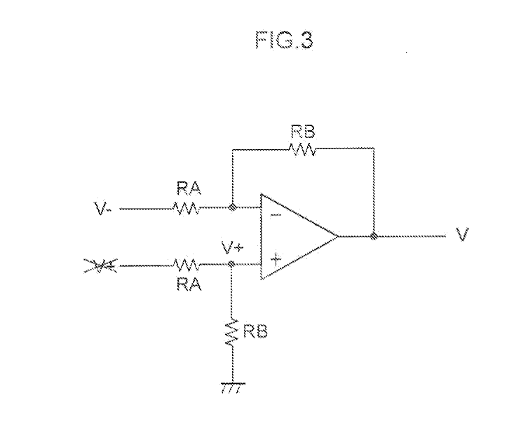

As shown in FIG. 3, when the position of the voltage V+ is moved immediately before the non-inverting input terminal of the subtractor, the output voltage V is complicated as represented by the following Equation 10.

$$\begin{matrix}V = ( V + ) + \frac{( V + ) - ( V - )}{{R}_{A}} \times {R}_{B} \\ = ( 1 + \frac{{R}_{B}}{{R}_{A}} ) ( V + ) - \frac{{R}_{8}}{{R}_{A}} ( V - )\end{matrix} \qquad Equation ( 10 )$$

Therefore, as shown in FIG. 1, the voltage V+ is disposed between the resistor R2 and the resistor R3 in order to simplify the output voltage V of the subtractor OP2.

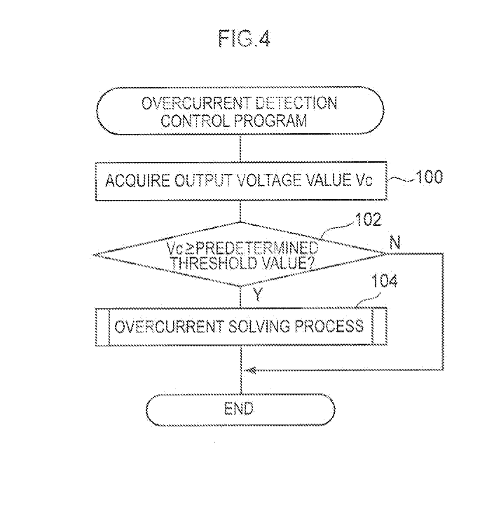

Next, the operation of the control unit 50 will be described with reference to FIG. 4. FIG. 4 is a flowchart of the flow of the process of an overcurrent detection control program executed by the control unit 50 at a predetermined time interval (in this exemplary embodiment, at an interval of 1 second) when the power supply device 10 is operated. The program is stored in a memory (not shown) provided in the control unit 50 in advance.

In the flowchart shown in FIG. 4, in Step 100, the voltage value V_{c} (hereinafter, referred to as an “output voltage value”) of the voltage applied from the output terminal of the comparator OP3 is acquired. In Step 102, it is determined whether the acquired output voltage value V_{c} is equal to a predetermined threshold value or more. The predetermined threshold value is set as the lower limit value of the output voltage value of the comparator OP3, when the voltage V− is higher than the voltage V. When the determination result is negative (No), the overcurrent detection control program ends. When the determination result is affirmative (Yes), the process proceeds to Step 104.

In Step 104, a predetermined process when the overcurrent flowing through the main transistor M5 is detected (hereinafter, referred to as an “overcurrent solving process”) is performed, and then the overcurrent detection control program ends.

In the overcurrent detection control program according to this exemplary embodiment, a process of stopping the application of a voltage to the gate of the main transistor M5 is performed as the overcurrent solving process, but the disclosure is not limited thereto. For example, any one of the following processes which suppresses defects caused by the overcurrent or combinations thereof may be applied in addition to the above-mentioned processes: a process of reducing the level of the voltage applied to the gate of the main transistor M5 by a predetermined value; a process of stopping the application of the power supply voltage V_{dd} to the drain of the main transistor M5; a process of shutting down a power supply path from the power circuit 20 to the load 90 and etc.

As described above, in this exemplary embodiment, a voltage corresponding to the power supply voltage generated by the power circuit is subtracted from the voltage between the drain and the source of the comparison transistor, and a voltage indicating the subtraction result is compared with a voltage corresponding to the source voltage of the main transistor. Therefore, the drain voltage of the comparison transistor can be converted into a voltage level based on the power supply voltage level by the subtraction. As a result, it is possible to accurately detect an overcurrent even when the main transistor is operated by the bootstrap.

In this exemplary embodiment, the comparison transistor and the main transistor are manufactured by the same process. Therefore, it is possible to more accurately detect an overcurrent.

This exemplary embodiment includes a first voltage-dividing resistor (resistors R2 to R4) that divides the voltage difference between the drain voltage of the main transistor and the source voltage of the comparison transistor and a second voltage-dividing resistor (resistors R7 and R8) that divides the voltage difference between the source voltage of the main transistor and the source voltage of the comparison transistor. The subtraction circuit subtracts the voltage divided by the first voltage-dividing resistor from the voltage difference between the drain and the source of the comparison transistor. The comparison circuit compares the voltage output from the subtraction circuit with the voltage divided by the second voltage-dividing resistor. Therefore, it is possible to obtain the subtraction result of the subtraction circuit and the comparison result of the comparison circuit at a desired voltage level. As a result, it is possible to accurately detect an overcurrent.

In this exemplary embodiment, the operation of the power circuit is controlled based on the detection result of the overcurrent detecting circuit. Therefore, it is possible to prevent the occurrence of defects due to an overcurrent.

### Second Exemplary Embodiment

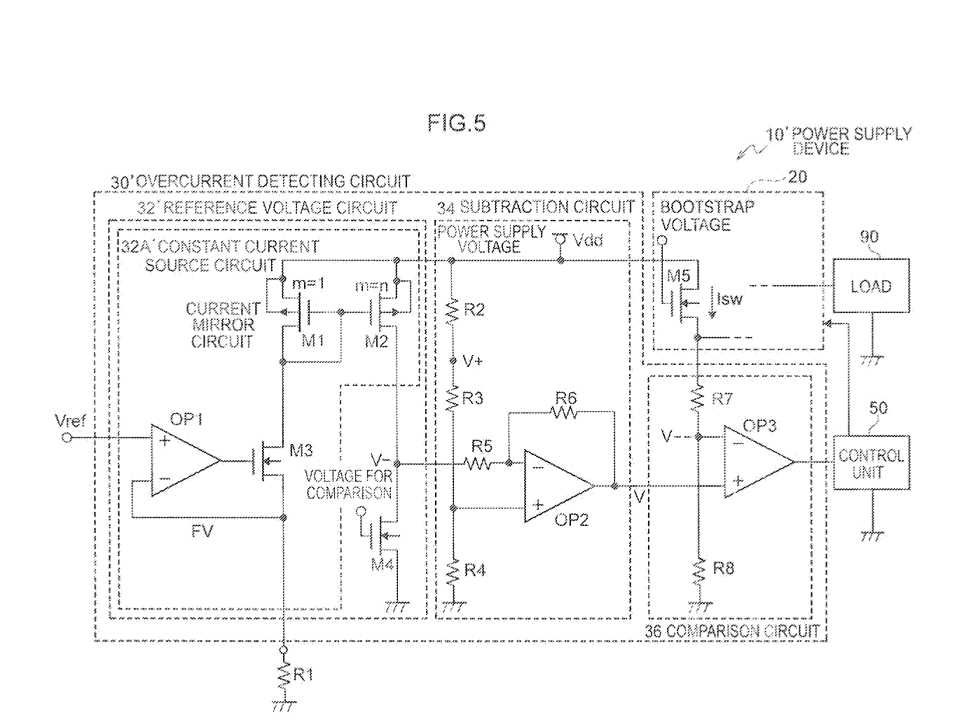

The structure of a power supply device 10′ according to a second exemplary embodiment will be described with reference to FIG. 5. In FIG. 5, the same components as those shown in FIG. 1 are denoted by the same reference numerals as those in FIG. 1, and a description thereof will be omitted.

As shown in FIG. 5, the power supply device 10′ according to the second exemplary embodiment differs from the power supply device 10 according to the first exemplary embodiment in that (i) an overcurrent detecting circuit 30′ is an integrated circuit and (ii) the resistor R1 is provided outside the integrated circuit.

As such, in the second exemplary embodiment, the overcurrent detecting circuit is configured as an integrated circuit and a resistor (resistor R1) for setting the current value of a constant current generated by the constant current source circuit is provided outside the integrated circuit. Therefore, it is possible to avoid the trimming of the integrated circuit in addition to the effects of the first exemplary embodiment.

In the first and second exemplary embodiments, the bootstrap voltage is applied to the gate of the main transistor M5, but the disclosure is not limited thereto. For example, a charge pump voltage may be applied to the gate of the main transistor M5. In this case, the power circuit 20 needs to be a charge pump type. According to this structure, it is possible to obtain the same effects as those in the first and second exemplary embodiments.

The structures of the power supply device 10 and the power supply device 10′ (see FIGS. 1 and 5) according to the first and second exemplary embodiments are just illustrative. An unnecessary component may be removed, a new component may be added, or the arrangement positions of the components may be changed without departing from the scope and spirit of the invention.

According to a first aspect of the disclosure, there is provided an overcurrent detecting circuit including: a comparison transistor which is used for comparison with a main transistor provided in a power circuit; a constant current source circuit which supplies a predetermined constant current to the comparison transistor; a subtraction circuit which subtracts a voltage corresponding to a power supply voltage generated by the power circuit from a voltage difference between a drain and a source of the comparison transistor and outputs a voltage indicating a subtraction result; and a comparison circuit which compares the voltage output from the subtraction circuit with a voltage corresponding to a source voltage of the main transistor and outputs a voltage indicating a comparison result.

According to the overcurrent detecting circuit of the first aspect, the constant current source circuit supplies a predetermined constant current to the comparison transistor which is used for comparison with the main transistor provided in the power circuit.

The subtraction circuit subtracts a voltage corresponding to the power supply voltage generated by the power circuit from the voltage between the drain and the source of the comparison transistor, and outputs a voltage indicating the subtraction result. The voltage corresponding to the power supply voltage generated by the power circuit includes the power supply voltage.

The comparison circuit compares the voltage output from the subtraction circuit with a voltage corresponding to the source voltage of the main transistor and outputs a voltage indicating the comparison result. The voltage corresponding to the source voltage of the main transistor includes the source voltage.

As such, according to the overcurrent detecting circuit of the first aspect, a voltage corresponding to the power supply voltage generated by the power circuit is subtracted from the voltage between the drain and the source of the comparison transistor, and a voltage indicating the subtraction result is compared with a voltage corresponding to the source voltage of the main transistor. Therefore, the drain voltage of the comparison transistor can be converted into a voltage level based on the power supply voltage level by the subtraction. As a result, it is possible to accurately detect an overcurrent even when the main transistor is operated by the bootstrap.

According to a second aspect of the disclosure, in the first aspect, the comparison transistor and the main transistor may be manufactured by the same process. In this way, it is possible to accurately detect an overcurrent.

According to a third aspect of the disclosure, in the first aspect, the overcurrent detecting circuit may further include: a first voltage-dividing resistor which divides a voltage difference between a drain voltage of the main transistor and a source voltage of the comparison transistor; and a second voltage-dividing resistor which divides a voltage difference between the source voltage of the main transistor and the source voltage of the comparison transistor, and the subtraction circuit may subtract the voltage divided by the first voltage-dividing resistor from the voltage between the drain and the source of the comparison transistor, and the comparison circuit may compare the voltage output from the subtraction circuit with the voltage divided by the second voltage-dividing resistor. In this way, it is possible to obtain the subtraction result of the subtraction circuit and the comparison result of the comparison circuit at a desired voltage level. As a result, it is possible to accurately detect an overcurrent.

According to a fourth aspect of the disclosure, in the first aspect, the overcurrent detecting circuit may be an integrated circuit, and the constant current source circuit may include a resistor that is provided outside the integrated circuit and sets a current value of the constant current generated by the constant current source circuit. In this way, it is possible to avoid the trimming of an integrated circuit when the overcurrent detecting circuit is the integrated circuit.

According to a fifth aspect of the disclosure, a power supply device including: a power circuit which includes: a main transistor whose overcurrent is detected by an overcurrent detecting circuit; and the overcurrent detecting circuit which includes: a comparison transistor which is used for comparison with the main transistor; a constant current source circuit which supplies a predetermined constant current to the comparison transistor; a subtraction circuit which subtracts a voltage corresponding to a power supply voltage generated by the power circuit from a voltage difference between a drain and a source of the comparison transistor and outputs a voltage indicating a subtraction result; and a comparison circuit which compares the voltage output from the subtraction circuit with a voltage corresponding to a source voltage of the main transistor and outputs a voltage indicating a comparison result.

The power supply device according to the filth aspect includes the overcurrent detecting circuit according to the disclosure. Therefore, similar to the overcurrent detecting circuit, it is possible to accurately detect an overcurrent even when the main transistor is operated by the bootstrap.

According to a sixth aspect of the disclosure, in the fifth aspect, the power supply device may further include a control unit which controls the operation of the power circuit based on a detection result of the overcurrent detecting circuit. In this way, it is possible to prevent the occurrence of defects due to an overcurrent.

In the fifth aspect, the power supply device may include the overcurrent detecting circuit according to the second to fourth aspects.

Although the exemplary embodiments of the disclosure have been described above, the technical scope of the invention is not limited to the range of the exemplary embodiments. Various modifications and changes of the disclosure can be made without departing from the scope and spirit of the invention, and the modifications and changes are also included in the technical scope of the invention.

The exemplary embodiments do not limit the invention described in the claims, and all combinations of the components according to the exemplary embodiments are not indispensable to the solving means of the invention. Structures in various stages are included in the above-described exemplary embodiments and plural components according to the above-described exemplary embodiments may be appropriately combined with each other to form various structures of the invention. Some of the components according to the above-described exemplary embodiments may be removed as long as the same effects as described above can be obtained.

Following from the above description and embodiment, it should be apparent to those of ordinary skill in the art that, while the foregoing constitute exemplary embodiments of the present disclosure, the disclosure is not necessarily limited to these precise embodiments and that changes may be made to these embodiments without departing from the scope of the invention as defined by the claims. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the disclosure discussed herein in order to fall within the scope of any claims, since the invention is defined by the claims and since inherent and/or unforeseen advantages of the present disclosure may exist even though they may not have been explicitly discussed herein.

What is claimed is:

1. An overcurrent detecting circuit comprising:
a comparison transistor which is used for comparison with a main transistor provided in a power circuit;
a constant current source circuit which supplies a predetermined constant current to the comparison transistor;
a subtraction circuit which subtracts a voltage corresponding to a power supply voltage generated by the power circuit from a voltage difference between a drain and a source of the comparison transistor and outputs a voltage indicating a subtraction result; and
a comparison circuit which compares the voltage output from the subtraction circuit with a voltage corresponding to a source voltage of the main transistor and outputs a voltage indicating a comparison result.

2. The overcurrent detecting circuit of claim 1, wherein the comparison transistor and the main transistor are manufactured by the same process.

3. The overcurrent detecting circuit of claim 1, further comprising:
a first voltage-dividing resistor which divides a voltage difference between a drain voltage of the main transistor and a source voltage of the comparison transistor; and
a second voltage-dividing resistor which divides a voltage difference between the source voltage of the main transistor and the source voltage of the comparison transistor,
wherein the subtraction circuit subtracts the voltage divided by the first voltage-dividing resistor from the voltage between the drain and the source of the comparison transistor, and
wherein the comparison circuit compares the voltage output from the subtraction circuit with the voltage divided by the second voltage-dividing resistor.

4. The overcurrent detecting circuit of claim 1, wherein:
the overcurrent detecting circuit is an integrated circuit, and
the constant current source circuit comprises a resistor that is provided outside the integrated circuit and sets a current value of the constant current generated by the constant current source circuit.

5. A power supply device comprising:
a power circuit comprising:
a main transistor whose overcurrent is detected by an overcurrent detecting circuit; and
the overcurrent detecting circuit comprising:
a comparison transistor which is used for comparison with the main transistor;
a constant current source circuit which supplies a predetermined constant current to the comparison transistor;
a subtraction circuit which subtracts a voltage corresponding to a power supply voltage generated by the power circuit from a voltage difference between a drain and a source of the comparison transistor and outputs a voltage indicating a subtraction result; and
a comparison circuit which compares the voltage output from the subtraction circuit with a voltage corresponding to a source voltage of the main transistor and outputs a voltage indicating a comparison result.

6. The power supply device of claim 5, further comprising a control unit which controls the operation of the power circuit based on a detection result of the overcurrent detecting circuit.

7. The power supply device of claim 5, wherein the comparison transistor and the main transistor are manufactured by the same process.

8. The power supply device of claim 5, wherein the overcurrent detecting circuit further comprises:
a first voltage-dividing resistor which divides a voltage difference between a drain voltage of the main transistor and a source voltage of the comparison transistor; and
a second voltage-dividing resistor which divides a voltage difference between the source voltage of the main transistor and the source voltage of the comparison transistor,
wherein the subtraction circuit subtracts the voltage divided by the first voltage-dividing resistor from the voltage between the drain and the source of the comparison transistor, and
the comparison circuit compares the voltage output from the subtraction circuit with the voltage divided by the second voltage-dividing resistor.

9. The power supply device of claim 5, wherein the overcurrent detecting circuit is an integrated circuit, and
the constant current source circuit comprises a resistor that is provided outside the integrated circuit and sets a current value of the constant current generated by the constant current source circuit.
